(19) United States
(12) Patent Application Publication
(10) Pub. No.: US 2002/0136253 A1
(43) Pub. Date: Sep. 26, 2002

(54) Semiconductor laser device and method for fabricating same

(75) Inventors: Norihiro Iwai, Tokyo (JP); Hitoshi Shimizu, Tokyo (JP); Toshikazu Mukaihara, Tokyo (JP); Akihiko Kasukawa, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC Co., Ltd., Tokyo (JP)

(21) Appl. No.: 09/811,454

(22) Filed: Mar. 20, 2001

(51) Int. Cl. H01S 5/00

(52) U.S. Cl. 372/45

(57) ABSTRACT

A semiconductor laser device including an InP-based substrate, and a laser structure overlying said InP-based substrate and configured to form a ridge stripe, said laser structure having a plurality of compound semiconductor layers including at least one selectively-oxidized layer forming a current confinement structure, said selectively-oxidized layer including a pair of Al-oxidized peripheral areas and a non-oxidized central area sandwiched therebetween and forming a current path for said laser structure. The semiconductor laser device has a reduced threshold current and excellent lasing characteristics by the function of the oxidized layer or a current blocking layer.

### BACKGROUND OF THE INVENTION

(a) Field of the Invention

The present invention relates to a semiconductor laser device, more in detail to the InP-based semiconductor laser device having a smaller threshold current and highly efficient operational characteristics, and a method for fabricating the same.

(b) Description of the Related Art

Recently, in the field of the semiconductor laser device, because of the demand for the simplicity of the process and the ease of the fabrication, a current confinement structure is frequently formed by using an Al oxide film having a higher electric resistance, in place of using a p-n junction structure formed by semiconductor layers, thereby reducing the threshold current of the semiconductor laser device.

Especially, the current confinement structure using the Al oxide film is extensively applied to a GaAs-based surface emission laser, which is effective for realizing a lower threshold and higher operational characteristics of the surface emission laser. The current confinement structure using the Al oxide film is also applied to a facet emission laser.

The configuration of the GaAs-based surface emitting semiconductor laser device having the current confinement structure and using the Al oxide film will be described referring to FIGS. 1A and 1B.

The GaAs-based surface emitting semiconductor laser device 40 having a current confinement structure using an Al oxide film (hereinafter referred to as “semiconductor laser device 40”) includes an n-GaAs substrate 41 having a thickness of about 100 μm, and a stacked structure formed thereon. The stacked structure includes an n-DBR mirror 42, a quantum well active layer 43 and a p-DBR mirror 44 stacked in this order on the substrate 41.

The n-DBR mirror 42 is formed as a multi-layered film structure having 22.5 pairs of layers each including an n-GaAs layer 42a and an n-AlAs layers 42, and the p-DBR mirror 44 is formed as a multi-layered film structure having 25 pairs of p-GaAs layers 44a and p-AlAs layers 44b.

The central portions of the respective two pairs in the p-DBR mirror 44, the quantum well active layer 43 and the n-DBR mirror 42 of the stacked structure are formed as a column-like air post 51 having a diameter of about 30 μm electrically separated from external elements by a buried polyimide layer 45.

As shown in Fig. 1B, Alₓ, O_{y} films 50 in contact with the polyimide layer 45 are disposed between the polyimide layer 45 and the AlAs layers 42b and 44b. Thereby, the diameter of the air post acting as a current injection area is about 20 μm smaller than that of the air post 51 itself having the diameter of about 30 μm.

A SiNₓ film 46 acting as a dielectric and protective film is deposited on the p-DBR mirror 44 and the polyimide layer 45 outside of the air post 51. An n-side electrode 48 having a ring structure is formed on the bottom surface of the n-GaAs substrate 41, a p-side electrode 47 is formed on the SiNₓ film 46 and the air post 51, and an AR (antireflection) film 49 for extracting light is formed inside of the n-side electrode 48.

Because of the efficiency of the semiconductor laser device 40 for reducing the threshold, the application of the current confinement structure using the Al oxide film to the InP-based semiconductor laser device has been frequently attempted to reduce the threshold current.

The problem of the above application is that the Al oxidized layer sufficiently thick for achieving the current confinement function is hardly obtained when the Al oxidized layer is formed by oxidation of the AlAs layer.

The problem arises due to the difference of lattice constant between the AlAs and the InP, which amounts to tensile strain of 3.5% . Accordingly, the AlAs layer having the required layer thickness for obtaining the Al oxidized layer achieving the current confinement function is hardly epitaxitially grown on the InP-substrate without relaxation which generates crystal lattice deficiencies.

In other words, the AlAs layer having the excellent crystal lattice and the desired thickness without the relaxation is hardly grown because of the difference between the lattice constants of the layers on the InP substrate when the AlAs layer acting as an oxidized layer is epitaxially grown though the Al oxidized layer having a specified thickness is required for acting as a current blocking layer of the semiconductor laser device. Accordingly, the restriction to the thickness of the AlAs layer appears.

As described above, although the current confinement structure having the Al oxidized layer obtained by oxidizing the AlAs layer is attractive for reducing the threshold current, the fabrication thereof on the InP-based semiconductor laser device is difficult due to the large difference of the lattice constants between the AlAs and the InP.

In case of the ridge-shaped wave-guide semiconductor laser device on the p-InP substrate, when the Al oxidized layer is formed on the n-semiconductor layer, the current spreads because the n-semiconductor layer having a lower electric resistance is present on the top portion of the active layer. Accordingly, the removal of the active layer is required, and the improvement of the reliability of the lasing characteristics is hardly attained.

### SUMMARY OF THE INVENTION

In view of the foregoing, an object of the present invention is to provide a semiconductor laser device with a current confinement structure formed by an oxide layer having excellent lasing characteristics.

Thus, the present invention provides, in a first aspect thereof, a semiconductor laser device including an InP-substrate, and a laser structure overlying said InP-substrate and configured to form a ridge stripe, said laser structure having a plurality of compound semiconductor layers including at least one selectively-oxidized layer forming a current confinement structure, said selectively-oxidized layer including a pair of Al-oxidized peripheral areas and a non-oxidized central area sandwiched therebetween and forming a current path for said laser structure.

In accordance with the first aspect of the present invention, the semiconductor laser device with the reduced threshold current and the excellent lasing characteristics can be realized.

The present invention provides, in a second aspect thereof, a method for forming a semiconductor laser device comprising the steps of: forming a ridge stripe including a semiconductor super-lattice layer having an AlAs layer with first compressive and tensile strains and a semiconductor layer with second compressive and tensile strains of a reverse direction with respect to the first compressive and tensile strains overlying a substrate; and thermally treating the semiconductor super-lattice layer in a vapor ambient to form Al oxidized peripheral areas on both ends of a non-oxidized central area sandwiched therebetween.

In accordance with the second aspect of the present invention, the blocking characteristic required for the lasing operation and the excellent AlAs crystals formed on the substrate without the stacking deficiency can be obtained by means of the optimization without occurring the relaxation during the crystal growth. Further, the fabrication method can be simplified while realizing the device characteristics similar to or higher than those of the conventional semiconductor laser device.

The above and other objects, features and advantages of the present invention will be more apparent from the following description.

### BRIEF DESCRIPTION OF DRAWINGS

FIG. 1A is a longitudinal sectional view showing a layer structure of a GaAs-based surface emission laser, and FIG. 1B is a detailed view showing part of an air post.

FIG. 2 is a longitudinal sectional view showing a super-lattice semiconductor layer structure usable in the present invention.

FIG. 3 is a graph showing dependency of an AlAs layer on the number of semi-layers.

FIG. 4 is a graph showing a current-voltage characteristic of an Al oxidized layer.

FIG. 5 is a longitudinal sectional view showing a layer structure of a semiconductor laser device sample.

FIG. 6 is a graph showing dependency of a ridge width (Wi) on a threshold current.

FIG. 7 is a graph showing dependency of an internal loss on the ridge width (Wi).

FIG. 8 is a graph showing dependency of the threshold current on an oxide aperture width (Wa) of an Al oxidized layer.

FIG. 9 is a graph showing dependency of a fundamental horizontal mode with on a distance (d) between the Al oxidized layer and an active layer.

FIG. 10 is a graph showing a current-voltage characteristic of an Al oxidized layer.

FIG. 11 is a graph showing dependency of the width of the Al oxidized layer on an oxidation time.

FIG. 12 is a longitudinal sectional view showing a layer structure of an InP-based semiconductor laser device in accordance with Embodiment 1 of the present invention.

FIG. 13A to 13C are longitudinal sectional views of the semiconductor laser device of Embodiment 1 sequentially showing a method for fabricating the semiconductor laser device.

FIG. 14 is a longitudinal sectional view showing a layer structure of an InP-based semiconductor laser device in accordance with Embodiment 2.

FIG. 15A to 15C are longitudinal sectional views of the semiconductor laser device of Embodiment 2 sequentially showing the method for fabricating the semiconductor laser device.

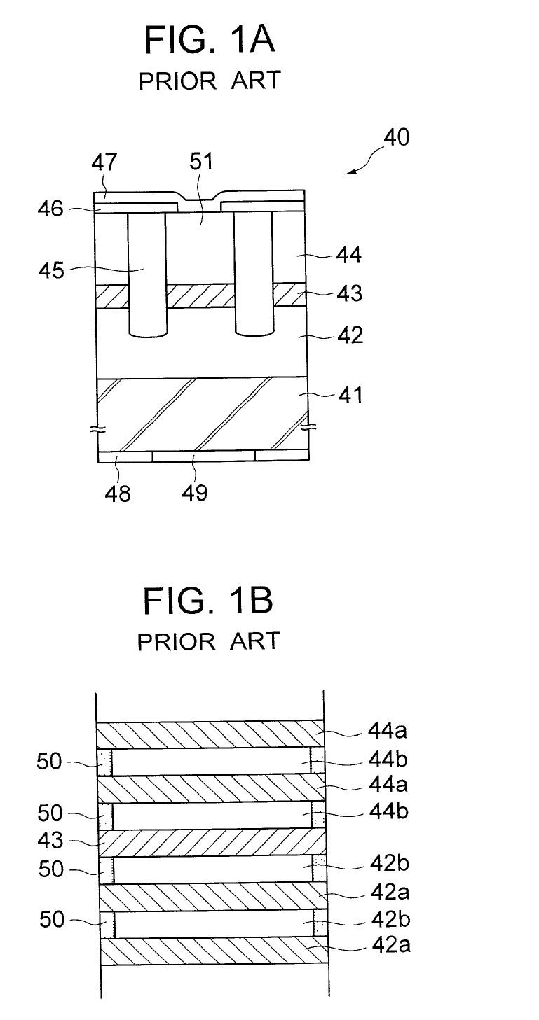

### PREFERRED EMBODIMENTS OF THE INVENTION

At first, principles of the present invention will be described for a purpose of clear understanding.

The present inventors have conducted a research in which a semiconductor layer having a compressive and tensile strains compensating structure is used as an oxidized layer because the inventors conceived that an AlAs layer having a specified thickness acting as the oxidized layer is stacked on an InP-substrate without deteriorating the crystalline property, for realizing the InP-based semiconductor laser device with a current confinement structure formed by an Al oxidized layer having excellent lasing characteristics.

A compressive and tensile strains compensating structure in which a first semiconductor layer having compressive and tensile strains is sandwiched by a pair of second semiconductor layers having compressive and tensile strains of a reverse direction is proposed as a means for increasing a total thickness of super-lattice layers by increasing the number of the pairs of the super-lattice layers having the compressive and tensile strains.

After the research of the AlAs film formation having a thicker total thickness on the InP-substrate based on the above technology, the present inventor have obtained the following findings.

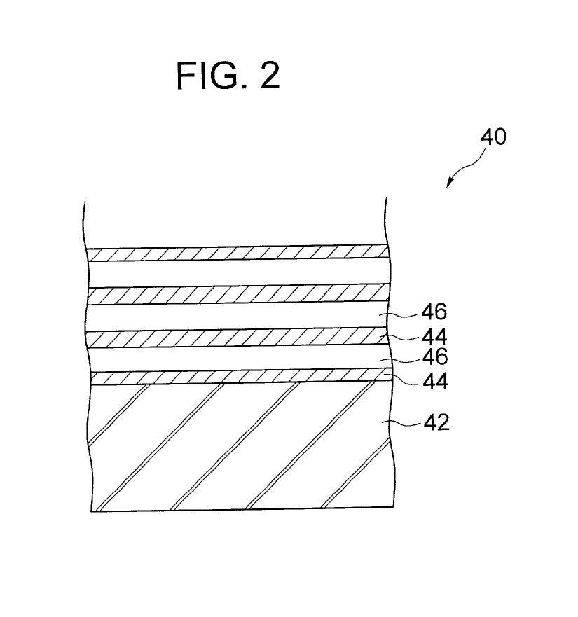

As shown in FIG. 2, the super-lattice semiconductor layer 40 includes AlInAs layers 44 and AlAs layers 46 alternately stacked with each other by using an MBE method on an InP substrate 42.

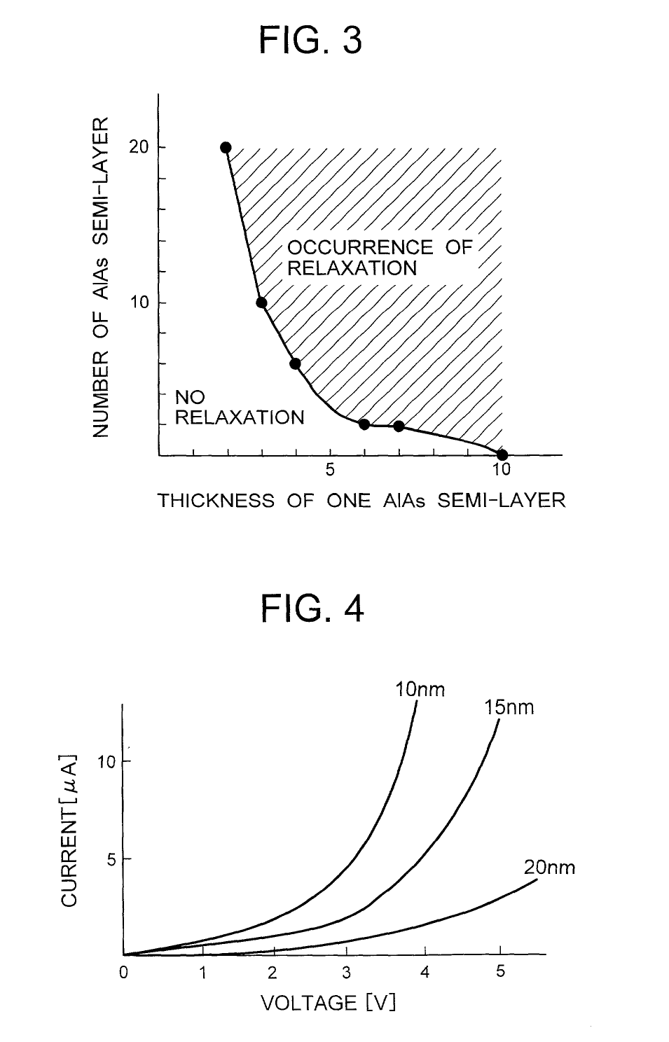

The present inventors have investigated that the relaxation occurs in which area in the super-lattice semiconductor layer 40 by changing the thickness of the single AlAs super-lattice layer and the number of the layers of the AlAs layer, and then obtained the results shown in a graph of FIG. 3 illustrating the dependency of the AlAs layers on the number of the layers in which the abscissa indicates a thickness of the single super-lattice layer and the ordinate indicates the number of layers of the AlAs layers. The thickness of the AlInAs layer for compensating the compressive and tensile strains of the AlAs layer was about 1.5 nm, and the amount of the compressive and tensile strains was +1%. The relaxation occurred in the area indicated with slanted lines in the graph.

The total thickness of the AlAs layer is a product between the thickness of the single AlAs super-lattice layer and the number of the layers thereof. For example, when the thickness of the single AlAs super-lattice layer is 5 nm or more, the total thickness of the AlAs layer is 15 nm or less because the number of the AlAs super-lattice layers for generating no relaxation is three at maximum. On the other hand, since no relaxation takes place for the AlAs layer having the six layers when the thickness of the single AlAs super-lattice layer is 4 nm or less, the total thickness of the AlAs super-lattice layer is 24 nm or less.

It can be judged from the graph of FIG. 3 that the thickness of the single AlAs super-lattice layer is made to be 4 nm or less for increasing the total thickness of the AlAs layer without the occurrence of the relaxation.

Similar results were obtained when the dependency of the AlAs layers on the number of the layers was examined for the sample of the super-lattice semiconductor layer as shown in FIG. 2 obtained by crystal growth using a metal organic chemical vapor deposition (MOCVD) method.

The present inventors have further investigated a voltage-current characteristic of an Al oxidized layer obtained by oxidizing the super-lattice semiconductor layer shown in FIG. 2 at a temperature of 500° C. in a vapor atmosphere produced by introducing water into a reaction furnace by using a pure water bubbler heated to about 85° C. and nitrogen gas as carrier. The result is shown in a graph of FIG. 4 in which a parameter is a thickness (nm) of the Al oxidized layer.

The driving voltage of the ordinary facet emission laser is about 2 V or less, and that of the surface emission laser having the highest driving voltage is about 4 V. In the current blocking layer formed by the ordinary p-n junction semiconductor layer, leakage current is reduced to several μA.

When these requirements are considered, the amount of the current in the semiconductor laser device at the voltage of 5 V is sufficient to be reduced to several μA. As shown in FIG. 4, the total thickness of the AlAs super-lattice layer for satisfying the above conditions is 20 nm or more.

### Optimization of Structure of Semiconductor Laser Device

The present inventors have further investigated the width and the thickness of the Al oxidized layer, the distance between the Al oxidized layer and an active layer, and the width of a current injection region after a Semiconductor laser device sample was fabricated in accordance with the method of the present invention as described below for optimizing the structure of the device having the internal current confinement structure having the Al oxidized layer overlying the InP substrate.

### Fabrication of Semiconductor laser device Sample

In the fabrication of the semiconductor laser device sample, a super-lattice layer was selected as an Al-containing oxidized layer, including, as a pair of stacked layers, AlAs layers having compressive and tensile strains and widely used as an oxidized layer and AlInAs layers having compressive and tensile strains of a reverse direction.

At first, an n-InP cladding layer 62, an SCH-MQW active layer 63, a p-InP cladding layer 64, six pairs of p-AlAs/p-AlInAs super-lattice oxidized layers 65, a p-InP cladding layer 66 and a p-GaInAs contact layer 67 were sequentially stacked on an n-InP substrate 61 by using the MOCVD method.

Then, the p-InP cladding layer 64 was halfway etched and removed by using a SiO₂ film as a mask to form striped ridges having a width of 10 μm.

The side surfaces of the super-lattice oxidized layers 65 were oxidized in water vapor at a temperature of about 500° C. for 150 minutes to form an Al oxidized layer 68.

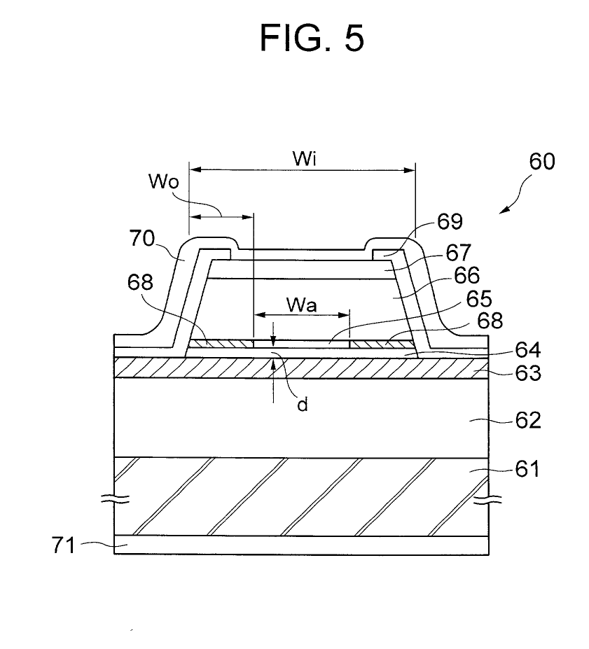

After a SiNₓ film 69 was formed on the wafer excluding the ridge, the n-InP substrate 61 was polished to a thickness of about 100 μm. A p-electrode 70 and an n-electrode 71 were formed to provide a first semiconductor laser device sample 60 as shown in FIG. 5.

A second semiconductor laser device sample was similarly fabricated by using an AlInAs layer as the Al-containing oxidized layer.

Then, the experiments and the calculations were conducted by using the first and the second semiconductor laser device samples to provide the results described below. ps 1) Optimization of Width (Wo) of Al Oxidized Layer

The optimization of the width (Wo) of the Al oxidized layer and the width (Wi) of the ridge was unnecessary when the Al oxidized layer was formed by oxidizing the AlAs layer in the ordinary GaAs-based semiconductor device because the oxidation speed of the AlAs layer was rapid.

However, in case of forming the Al oxidized layer by oxidizing the thin AlAs layer such as the super-lattice layer, and the AlInAs layer having a lower Al-containing rate, a longer time is required for oxidizing the Al-containing oxidized layer in the actual fabrication method, due to an excessively low oxidation rate, to hardly improve the productivity when the ridge having a much larger width is formed to increase the width of the Al-containing oxidized layer.

Accordingly, the formation of the ridge having a smaller width for providing the Al oxidized layer having a smaller width is important so long as the reduction of the width does not exert a harmful influence to the lasing characteristics.

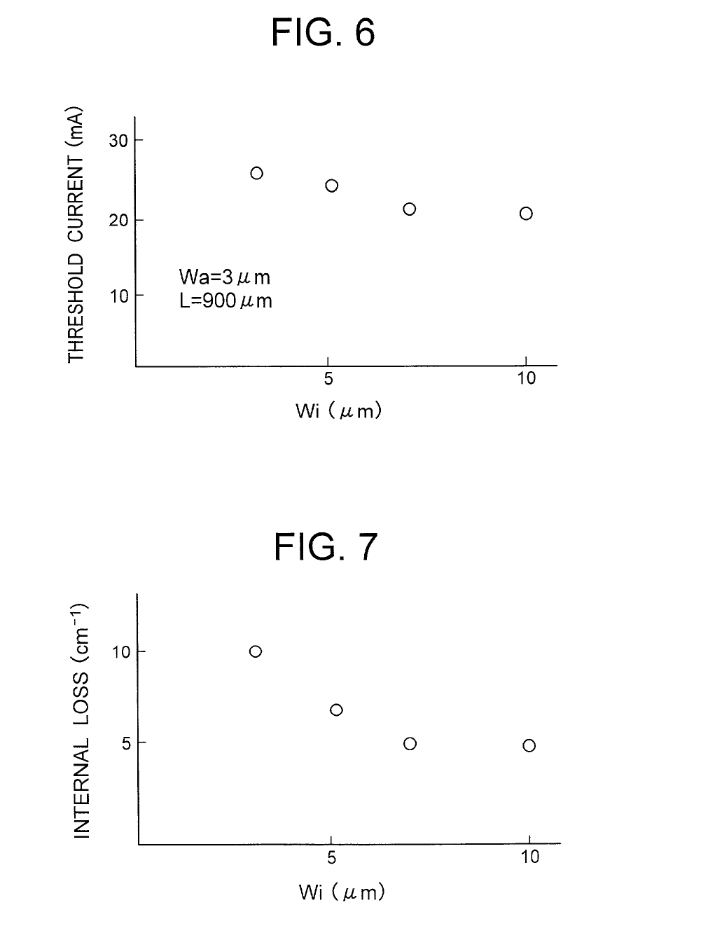

The present inventors have investigated the dependency of the ridge width (Wi) on the threshold current to obtain the result shown in a graph of FIG. 6. The semiconductor laser device sample used in the experiment included non-coated both facets, and had a cavity length of 900μm and an oxide aperture width (Wa) of the Al oxidized layer of 3.0μm.

As shown in FIG. 6, the threshold current decreased with increase of the ridge width (Wi) and remained constant and low at the ridge width of 7 μm or more.

The device having the oxide aperture width of the Al oxidized layer of 3.0 μm may have a width (Wo) of the Al oxidized layer of 2 μm shown in FIG. 5 for reducing the threshold. Or the ridge width (Wi) may be larger than the oxide aperture width of the Al oxidized layer by 4 μm or more.

As shown in FIG. 5, the ridge width (Wi) extends from one ridge end of the Al-containing oxidized layer to the other, and the width (Wo) of the Al oxidized layer 68 extends from the outer edge thereof to the inner edge thereof.

The present inventors have investigated the dependency of the internal loss on the ridge width (Wi) to obtain the result shown in a graph of FIG. 7. As shown therein, the internal loss decreased with the increase of the ridge width (Wi) and remained constant and low at the ridge width of 7 μm or more.

The optical field penetrated to the ridge end to cause the scattering loss on the ridge end, thereby increasing the internal loss. The dependency of the internal loss on the ridge width (Wi) was interrupted in this manner.

2) Optimization of Oxide Aperture Width (a) of Al oxidized layer and Distance (d) Between Al oxidized layer and Active Layer

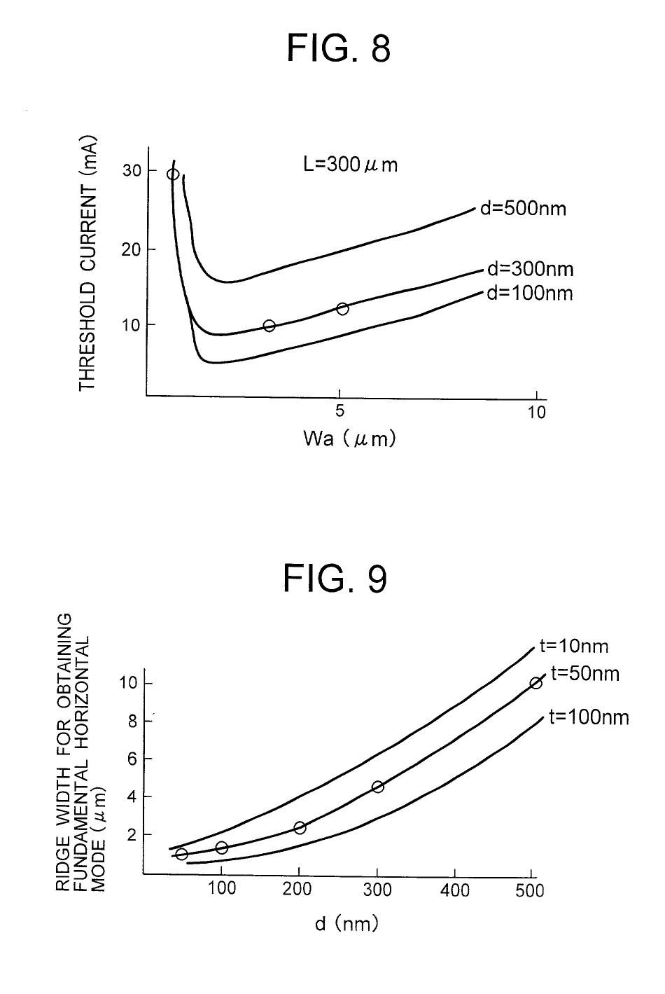

The present inventors have investigated, through the experiment and the calculation, the dependency of the threshold current on the oxide aperture width (Wa) of the Al oxidized layer by using, as a parameter, the distance (d) between the Al oxidized layer and the active layer to obtain the result shown in a graph of FIG. 8 in which ◯indicated the data obtained in experiments. The semiconductor laser device sample used in the experiment and the calculation had a cavity length of 300 μm and a reflectivity of a rear facet of 96 % .

As shown in FIG. 5, the oxide aperture width (Wa) of the Al oxidized layer is that of the non-oxidized layer of the Al-containing oxidized layer, and the distance (d) is that between the bottom surface of the Al oxidized layer 68 and the top surface of the active layer 63.

As shown in FIG. 8, the threshold current reduced with the increase of the oxide aperture width (Wa) of the Al oxidized layer and reached to minimum at about 1.5 μm and increased with the further increase of the oxide aperture width. The increase (worsening) of the threshold current at the reduced oxide aperture width below 1.5 μm is due to the smaller light confinement in the horizontal direction.

When the oxide aperture width (Wa) was constant, the threshold current decreased with the decrease of the distance (d) between the oxide layer and the active layer. This is because the current spread therebetween was suppressed.

When only the threshold current was considered, the oxide aperture width (Wa) of the Al oxidized layer was preferably about 1.5 μm, and the distance (d) between the oxide layer and the active layer was preferably smaller or as close as possible to zero.

As a characteristic for determining the quality of the semiconductor laser, a kink characteristic is used. The kink is a phenomenon occurring in the transition from the fundamental horizontal mode of the semiconductor laser device to the multi-mode thereof when the amount of the injection current is increased. In the kink phenomenon, the current-light output characteristic shows a zigzag curve, and the efficiency change in the kink phenomenon is defined to be about 5 % .

The occurrence of the kink phenomenon is determined by the structure of the wave-guide path, and especially in the ridge-shaped semiconductor laser device, the kink is one of the factors for reducing the yield.

The cut-off condition of the higher order mode of the horizontal mode is defined by the following equation by using a refraction rate of a light-emitting section, a difference of the refraction rates of both sections sandwiching the light-emitting section and the ridge width, wherein W is a width of the active layer when the higher order mode is cut-off, λA is a lasing wavelength, Δn is a difference between equivalent refraction rates and “nr” is a refraction rate of a medium.

W=λ/[2(2Δn)1/2nr]

A permitted range of the ridge width for maintaining the fundamental horizontal mode is increased when the equivalent refraction rate difference is smaller.

In the semiconductor laser device having the confining structure by the Al oxidized layer such as that of the present invention, the equivalent refraction rate difference tends to be larger by reducing the distance “d” between the oxide layer and the active layer or by increasing the thickness “t” of the Al oxidized layer.

The dependency of the fundamental horizontal mode width on the distance between the Al oxidized layer having a thickness of 50 nm and the active layer was calculated. The result is shown in a graph of FIG. 9.

As shown therein, the ridge width for obtaining the fundamental horizontal mode is naturally narrowed with the reduction of the distance “d”. When the distance “d” is 100 nm or less, the ridge width is must be 1.5 μm. In the previous results of the threshold current in which the oxide aperture width must be 1.5 μm or more, the distance “d” must be 100 nm or more.

The excessively larger distance increases the threshold current. Accordingly, the optimum ranges of the Wa and “d” are between 1.5 μm and 4 μm and between 100 nm and 300 nm, respectively, when the lasing characteristics and the fabrication steps are considered.

3) Optimization of Thickness “t” of Al oxidized layer

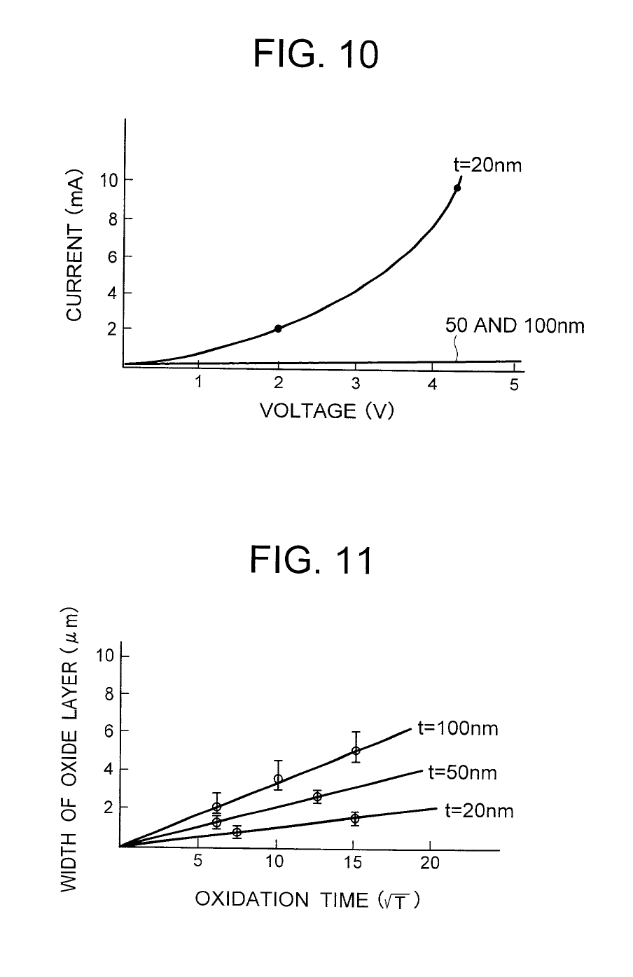

The most important factor with respect to the thickness of the Al oxidized layer is the current blocking (insulating) characteristic. The current-voltage characteristic of the Al oxidized layer using the thickness “t” of the Al oxidized layer as a parameter is shown in FIG. 10 in which the thickness of the Al oxidized layer were 20 nm, and 50 and 100 nm.

As shown in FIG. 10, the Al oxidized layer having the thickness of 20 nm or more is satisfactorily used as the blocking layer of the semiconductor laser device.

Then, the dependency of the width of the Al oxidized layer on the time required for oxidation is shown in a graph of FIG. 11 when the AlInAs layer was oxidized using the thickness “t” of the oxidize layer as a parameter.

As shown therein, the oxidation rate increased with the increase of the oxidized layer thickness. The increased thickness can shorten the time required for the oxidation. This tendency was similarly observed in case of the AlAs/AlInAs super-lattice layer.

The irregularity of the width of the Al oxidized layer was reduced with the decrease of the thickness thereof. The thickness of the Al oxidized layer is preferably 100 nm or less to reduce the irregularity of the width when the lasing characteristics and the fabrication steps are considered. In case of the AlAs/AlInAs super-lattice layer, the thickness is preferably as small as possible for obtaining the film having the stable and excellent characteristics even if the compressive and tensile strains compensation is applied.

When the blocking characteristic, the oxidation rate, the control of the oxidation and the productivity are considered, the optimum width of the Al oxidized layer is in a range between 20 and 100 nm based on the previous results.

Similar results were obtained in the two semiconductor laser device samples. One of the samples had the AlAs/AlInAs super-lattice layer as the Al-containing oxidized layer, and the other had the AlInAs layer as the Al-containing oxidized layer.

Based on the above experiments and researches, the width of the Al oxidized layer of the semiconductor laser device is preferably 2.0μm or more. The oxide aperture width (width of current injection area) is preferably between 1.5 and 4.0 μm. The distance between the Al oxidized layer and the active layer is preferably between 100 and 300 nm. The thickness of the Al oxidized layer or the oxidized layer is preferably between 20 and 100 nm.

Similar results for the optimization were obtained when AlAs-based compound semiconductor materials other than above were used as the Al-containing oxidized layer.

Now, the present invention is more specifically described with reference to accompanying drawings.

### Embodiment 1

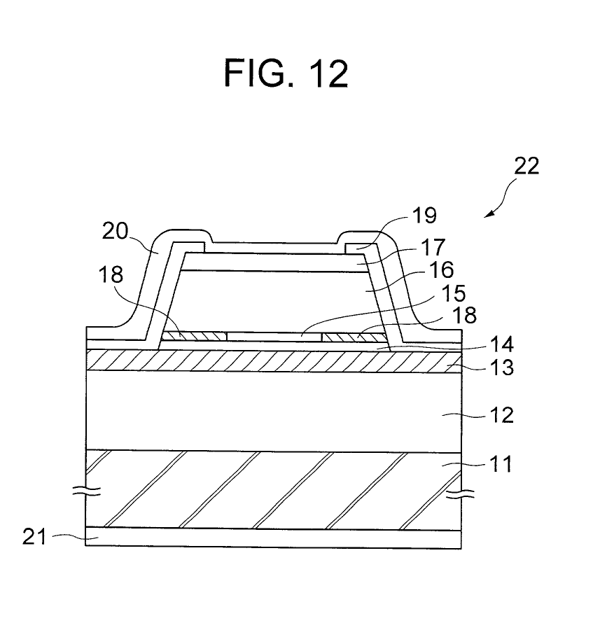

An InP-based semiconductor laser device 22 shown in FIG. 12 is a ridge-shaped wave-guide based semiconductor laser device having a current confinement structure formed by an Al oxide film 18 obtained by oxidizing an AlAs super-lattice layer, overlying an n-InP substrate.

The InP-based semiconductor laser device 22 includes a stacked ridge-shaped structure with a width of 7 μm having an n-InP cladding layer 12 having a thickness of 0.5 μm, an SCH-MQW active layer 13, a p-InP cladding layer 14 having a thickness of 0.2 μm, a p-AlAs/p-AlInAs super-lattice layer 15, a p-InP cladding layer 16 having a thickness of 1.5 μm and a p-GaInAs contact layer 17 having a thickness of 0.3 μm sequentially stacked on an n-InP substrate 11.

In the p-AlAs/p-AlInAs super-lattice layer 15, the thickness of one layer of an AlAs super-lattice layer is 4 nm, the number of layers is six, and the total thickness of the AlAs layer is 24 nm. The thickness of the AlInAs layer is about 1.5 nm, and the amount of the tensile strains is +1.5% .

Part of the p-AlAs/p-AlInAs super-lattice layer 15 or from both the ridge side surfaces toward the inner part by about 2 μm is oxidized to be converted into an Al oxidized layer 18. Specifically, the p-AlAs/p-AlInAs super-lattice layer 15 includes the Al oxidized layer 18 having a width of about 2 μm from the one ridge side surface to the inner part, then the p-AlAs/p-AlInAs super-lattice layer 15 having a width of about 3 μm, and the Al oxidized layer 18 having a width of about 2 μm from the interface to the other ridge side surface. The width of about 3 μm of the p-AlAs/p-AlInAs super-lattice layer 15 is defined as a current injection width.

A SiNₓ film 19 acting as a dielectric and protective film is deposited on the p-GaInAs contact layer 17 and the ridge side surface excluding the current injection area.

A p-side electrode 20 is formed on the current injection area and the SiNₓ. film 19 of the top part of the ridge, and an n-side electrode 21 is formed on the bottom surface of the substrate 11.

In the InP-based semiconductor laser device 22 of Embodiment 1, the threshold current which is an important factor of the lasing characteristics is significantly reduced because the SCH-MQW active layer 13 is present closely to the Al oxidized layer (current blocking layer) 18 through intermediary of only the thin p-InP cladding layer 14 having the thickness of 0.2 μm. The p-InP cladding layer may be omitted because the Al oxidized layer is desirably located closely to the active layer as much as possible.

The InP-based semiconductor laser device 22 of Embodiment 1 includes the thicker Al oxidized layer 18 because of the optimization of the p-AlAs/p-AlInAs super-lattice layer 15 acting as the oxidized layer based on the graph of FIG. 3.

Since the width of the current injection area (pAlAs/p-AlInAs super-lattice layer 15) can be controlled by the internal extension of the Al oxidized layer 18 or the width of the Al oxidized layer 18, the ridge width can be increased in the ridge forming step to simplify the fabrication.

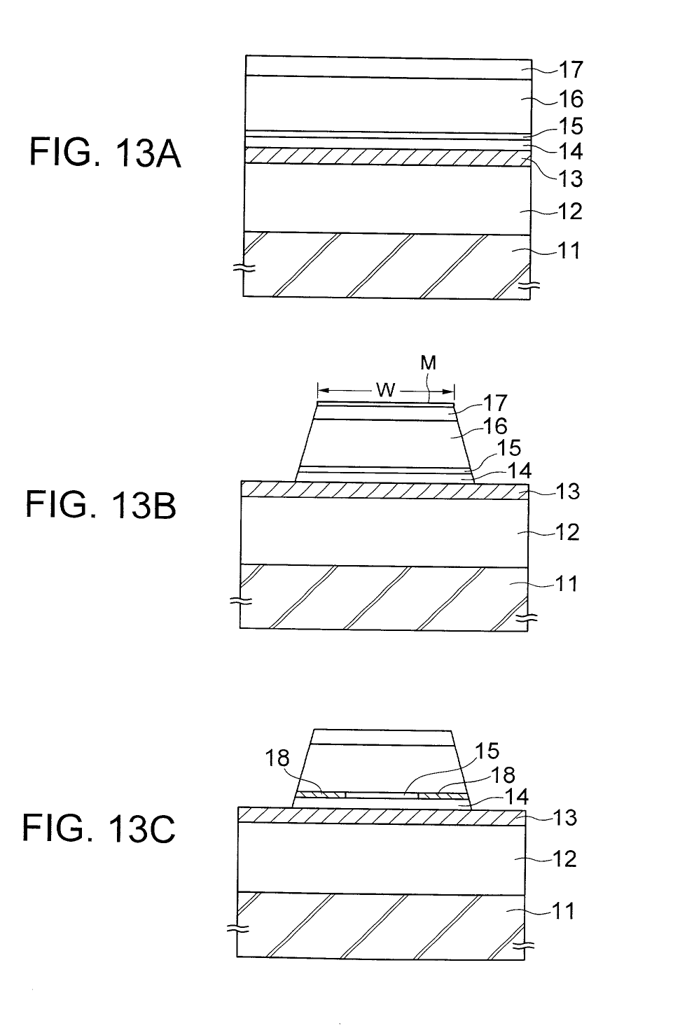

Then, a method for fabricating the InP-based semiconductor laser device 22 of Embodiment 1 will be described referring to FIGS. 13A to 13C.

As shown in FIG. 13A, an n-InP cladding layer 12 having a thickness of 0.5μm, an SCH-MQW active layer 13, a p-InP cladding layer 14 having a thickness of 0.2 μm, a p-AlAs/p-AlInAs super-lattice oxidized layers 15, a p-InP cladding layer 16 having a thickness of 1.5 μm and a p-GaInAs contact layer 17 having a thickness of 0.3 μm are sequentially stacked on a n-InP substrate 11 by using a gas source MOCVD apparatus.

Then, as shown in FIG. 13B, a SiO₂ film is deposited on the contact layer 17, and a mask “M” is formed by patterning the SiO₂ film. Thereafter, the contact layer 17, the p-InP cladding layer 16, the super-lattice layer 15 and the p-InP cladding layer 14 are etched by using the mask “M” in accordance with a RIBE (RIE) method, thereby forming a ridge having a width “W” of 7 μm.

Then, water vapor is introduced into a reaction furnace by using a pure water bubbler heated to about 85° C. and nitrogen gas as a carrier to make a water vapor ambient. The ridge-shaped wafer is then thermally treated in the reaction furnace having the vapor ambient at about 500° C. for 150 minutes. Thereby, as shown in FIG. 13C, the peripheral part of the p-AlAs/p-AlInAs super-lattice layer 15 from the edge to the inner part by about 2 μm is oxidized to form the Al oxidized layer 18. The current injection width or the oxide aperture width surrounded by the Al oxidized layer 18 formed in this manner is about 3 μm.

Then, as shown in FIG. 12, after a SiNₓfilm 19 is formed on the wafer excluding the current injection area existing on the top part of the ridge and the wafer is polished to a thickness of about 100μm, a p-side electrode 20 is formed on the current injection area and the SiNₓ film 19, and an n-side electrode 21 is formed on the bottom surface of the substrate 11.

### Embodiment 2

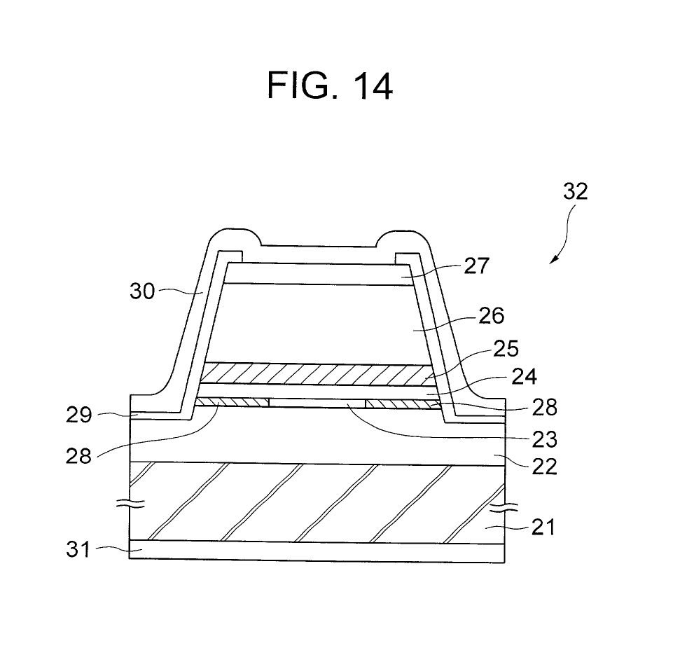

An InP-based semiconductor laser device 32 shown in FIG. 14 is a ridge-shaped wave-guide based semiconductor laser device having a current confinement structure formed by an Al oxide film 28 obtained by oxidizing an AlAs super-lattice layer, overlying a p-InP substrate.

The InP-based semiconductor laser device 32 includes a stacked ridge-shaped structure with a width of 7 μm having a p-InP cladding layer 22 having a thickness of 2.0 μm, a p-AlAs/p-AlInAs super-lattice layer 23, a p-InP cladding layer 24 having a thickness of 0.2 μm, an SCH-MQW active layer 25, an n-InP cladding layer 26 having a thickness of 1.5 μm and an n-GaInAs contact layer 27 having a thickness of 0.3 μm sequentially stacked on a p-InP substrate 21 having a thickness of about 100 μm.

In the p-AlAs/p-AlInAs super-lattice layer 23, the thickness of one layer of an AlAs super-lattice layer is 4 nm, the number of layers is six, and the total thickness of the AlAs layer is 24 nm. The thickness of the AlInAs layer is about 1.5 nm, and the amount of the compressive and tensile strains is +1.5% .

Part of the p-AlAs/p-AlInAs super-lattice layer 23 or from both the ridge side surfaces toward the inner part by about 2 μm is oxidized to be converted into an Al oxidized layer 28. Specifically, the p-AlAs/p-AlInAs super-lattice layer 23 includes the Al oxidized layer 28 having a width of about 2 μm from the one ridge side surface to the inner part, then the p-AlAs/p-AlInAs super-lattice layer 23 having a width of about 3 μm, and the Al oxidized layer 28 having a width of about 2 μm from the interface to the other ridge side surface. The width of about 3 μm of the AlAs/p-AlInAs super-lattice layer 23 is defined as a current injection width.

A SiNₓ film 29 acting as a dielectric and protective film is deposited on the p-GaInAs contact layer 27 and the ridge side surface excluding the current injection area.

A p-side electrode 30 is formed on the current injection area and the SiNₓfilm 29 of the top part of the ridge, and an n-side electrode 31 is formed on the bottom surface of the substrate 21.

In general, in the semiconductor laser device including the p-substrate, the current spreads to increase the threshold current because the resistance of the n-semiconductor layer is low even if the ridge is formed in the top part of the active layer or the n-semiconductor layer. Accordingly, the active layer is also removed to form the ridge. This is a problem in the conventional semiconductor laser device having the ridge-shaped structure formed on the p-substrate.

On the other hand, in Embodiment 2, the current is concentrated to the central part of the ridge by means of the current confinement function of the Al oxidized layer even when the ridge is formed by etching the active layer. Only the central area of the active layer acts as a light emitting area, which is not affected by ridge surface of the active layer. Accordingly, the ridge-shaped wave-guide semiconductor laser device having the excellent characteristics can be realized on the p-InP substrate.

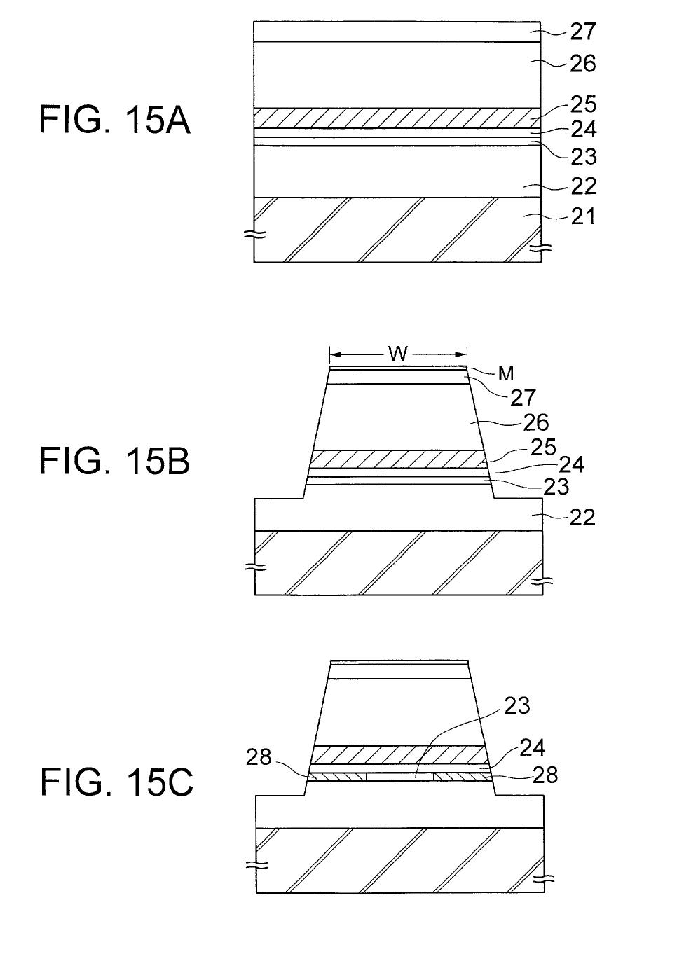

Then, a method for fabricating the InP-based semiconductor laser device 32 of Embodiment 2 will be described referring to Figs.15A to 15C.

As shown in FIG. 15A, a p-InP cladding layer 22 having a thickness of 2.0 μm, a p-AlAs/p-AlInAs super-lattice layer 23, a p-InP cladding layer 24 having a thickness of 0.2 μm, an SCH-MQW active layer 25, an n-InP cladding layer 26 having a thickness of 1.5 μm and an n-GaInAs contact layer 27 having a thickness of 0.3 μm are sequentially stacked on a p-InP substrate 21 by using a gas source MOCVD apparatus.

Then, as shown in FIG. 15B, a SiO₂ film is deposited on the contact layer 27, and a mask “M” is formed by patterning the SiO₂ film. Thereafter, the contact layer 27, the p-InP cladding layer 26, the SCH-MQW active layer 25, the p-InP cladding layer 24, the super-lattice layer 23 and the p-InP cladding layer 22 are halfway etched by using the mask “M” in accordance with a RIBE (or RIE) method, thereby forming a ridge having a width “W” of 7 μm.

Then, water vapor is introduced into a reaction furnace by using a pure water bubbler heated to about 85° C. and nitrogen gas as a carrier to make a water vapor ambient. The ridge-shaped wafer is then thermally treated in the reaction furnace having the vapor ambient at about 500° C. for 150 minutes. Thereby, as shown in FIG. 15C, the peripheral part of the AlAs/AlInAs super-lattice layer 23 from the edge to the inner part by about 2 μm is oxidized to form the Al oxidized layer 28. The current injection width or the oxide aperture width surrounded by the Al oxidized layer 18 formed in this manner is about 3 μm.

Then, as shown in FIG. 14, after a SiNₓ. film 29 is formed on the wafer excluding the current injection area existing on the top part of the ridge and the wafer is polished to a thickness of about 100 μm, an n-side electrode 30 is formed on the current injection area and the SiNₓ film 29, and a p-side electrode 31 is formed on the bottom surface of the substrate 21.

Since the above embodiments are described only for examples, the present invention is not limited to the above embodiments and various modifications or alterations can be easily made therefrom by those skilled in the art without departing from the scope of the present invention.

What is claimed is:

1. A semiconductor laser device comprising an InP-substrate, and a laser structure overlying said InP-substrate and configured to form a ridge stripe, said laser structure having a plurality of compound semiconductor layers including at least one selectively-oxidized layer forming a current confinement structure, said selectively-oxidized layer including a pair of Al-oxidized peripheral areas and a non-oxidized central area lo sandwiched therebetween and forming a current path for said laser structure.

2. The semiconductor laser device as defined in claim 1, wherein said at least one selectively-oxidized layer includes at least one p-type cladding layer.

3. The semiconductor laser device as defined in claim 2, wherein said at least one p-type cladding layer forming a super-lattice structure having a plurality of pair of layers each including an AlAs layer having one of compressive and tensile strains and a first semiconductor layer having the other of compressive and tensile strains and formed thereon.

4. The semiconductor laser device as defined in claim 3, wherein said first semiconductor layer is implemented by either an AlInAs layer or an AlGaInAs layer.

5. The semiconductor laser device as defined in claim 3 or 4, wherein one of said AlAs layers has a thickness of 4 nm or less, and said AlAs layers have a total thickness of 20 nm or above.

6. A method for forming a semiconductor laser device comprising the steps of:
forming a ridge stripe including a semiconductor super-lattice layer having an AlAs layer with first compressive and tensile strains and a semiconductor layer with second compressive and tensile strains of a reverse direction with respect to the first compressive and tensile strains overlying a substrate; and
thermally treating the semiconductor super-lattice layer in a vapor ambient to form Al oxidized peripheral areas on both ends of a non-oxidized central area sandwiched therebetween.

7. The method as defined in claim 6, wherein a thickness of a semi-layer of the AlAs layer constituting the semiconductor super-lattice layer and the number of the AlAs semi-layers are determined such that the AlAs layer has a specified total thickness calculated from a relation between the thickness of the semi-layer of the AlAs layer and the number of the AlAs semi-layers without occurrence of crystal relaxation.
